(19) United States
(12) Patent Application Publication
(10) Pub. No.: US 2018/0316440 A1
(43) Pub. Date: Nov. 1, 2018

(54) OPTICAL RECEIVER, OPTICAL TERMINATION DEVICE, AND OPTICAL COMMUNICATION SYSTEM

(71) Applicant: Mitsubishi Electric Corporation, Tokyo (JP)

(72) Inventor: Daisuke MITA, Tokyo (JP)

(73) Assignee: Mitsubishi Electric Corporation, Tokyo (JP)

(21) Appl. No.: 15/768,903

(22) PCT Filed: Dec. 21, 2015
(86) PCT No.: PCT/JP2015/085661

§ 371 Date: Apr. 17, 2018

(51) Int. Cl. H04B 10/69; H03F 1/08; H03F 1/02; H03F 3/08

(52) U.S. Cl. CPC H04B 10/697; H03F 1/086; H03F 2200/129; H03F 3/082; H03F 2200/462; H03F 1/0233

(57) ABSTRACT

An optical receiver includes: a light reception element to convert an input optical signal into a first current signal and output the first current signal; an inverter-based TIA to convert the first current signal into a voltage signal and output the voltage signal using first and second field effect transistors; a current monitor unit to monitor a current magnitude of the first current signal and output a second current signal having a current magnitude based on the current magnitude of the first current signal; and a back-gate adjustment unit to determine a state of an input-output characteristic of the inverter-based TIA on the basis of the second current signal and the voltage signal, and control, on the basis of the determination result, a back-gate terminal voltage of at least one of the first and second field effect transistors.

### FIELD

The present invention relates to an optical receiver, an optical termination device, and an optical communication system that include a transimpedance amplifier that converts a current signal input from a light reception element into a voltage signal.

### BACKGROUND

In recent years, the expansion of mobile broadband services due to rapid spread of smart devices and further spread of Internet services, such as social network services, cloud computing, and video distribution, have been causing a rapid increase in communication traffic. This has increased the importance of data centers that support these services. There is a demand for a higher capacity not only in communication between a data center and buildings but also in communication between data centers, thereby leading to studies on even higher capacity of optical communication.

In addition to increasing the communication capacity, a further reduction in power consumption is another issue for a data center. In a data center, an increase in communication traffic has led to an increase in the number of information and communication technology (ICT) devices, such as a server, causing these ICT devices to serve as heat sources and thus to generate a large amount of heat. Accordingly, a large amount of electricity is consumed by the air conditioning system for cooling the place. This also requires a further reduction in power consumption in the ICT devices, in the optical transceivers for communication, and in integrated circuits (ICs) themselves included in the optical transceivers.

Such trend of demands for a higher communication capacity and a further reduction in power consumption is also observed in communication between servers and in communication between central processing units (CPUs). The introduction of server virtualization technology gets underway and this requires a higher capacity in communication between servers and in communication between CPUs. However, electrical wiring presents a problem in that an increase in communication speed imposes a limitation on the wire length and results in more power consumption related to power efficiency. To address the problems with respect to electrical wiring, optical wiring technologies are being studied, and there is an increasing movement to deploy optical wiring not only for communication between servers but also for communication between ICs, such as CPUs within a board. Because of such a background, studies are being conducted on the use of a transimpedance amplifier (TIA) in optical wiring. In addition, a further reduction in power consumption of TIA is also being studied.

Patent Literature 1 discloses a technology that provides a further reduction in power consumption by using, in a TIA, a digital circuit constituted by a metal oxide semiconductor field effect transistor (MOSFET). However, despite being useful for a further reduction in power consumption, the TIA described in Patent Literature 1 has a disadvantage in that there is no one-to-one correspondence between the received light level of an optical signal that is input and the output voltage level, meaning that linearity cannot be maintained.

Non Patent Literature 1 discloses a technology that improves linearity in an inverter-based TIA. The TIA described in Non Patent Literature 1 consumes more electrical power than the TIA described in Patent Literature 1, but can reduce power consumption more than an analog TIA circuit, and at the same time, can maintain linearity more easily than the TIA described in Patent Literature 1.

### CITATION LIST

### Patent Literature

Patent Literature 1: Japanese Patent Application Laid-open No. 2013-157731

### Non Patent Literature

Non Patent Literature 1: Y. Wang et al., “A 3-mW 25-Gb/s CMOS transimpedance amplifier with fully integrated low-dropout regulator for 100 GbE systems” , Radio Frequency Integrated Circuits Symposium, 2014 IEEE; pp. 275-278, 1-3 Jun. 2014.

### SUMMARY

### Technical Problem

However, as compared to an analog TIA circuit, the TIA of Non Patent Literature 1 also has a disadvantage in linearity as follows. In the TIA of Non Patent Literature 1, a high received-light level or a high extinction ratio of the optical signal causes a high current to flow from the light reception element through a feedback resistor and the drain terminal of an NMOS (N-type MOSFET) to ground. In a TIA, the output terminal voltage decreases in accordance with the current magnitude and the resistance value of the feedback resistor, and the TIA has a disadvantage in that a further decrease in the output terminal voltage becomes restricted at a certain voltage level, thereby causing nonlinearity and thus causing distortion of the waveform of the output terminal voltage.

Moreover, a nonlinear characteristic deteriorates the dynamic range characteristic of the TIA. In a TIA, since the drain current magnitude in the NMOS is proportional to the gate width and is inversely proportional to the gate length, an increase in the gate width, i.e., an increase in the size of the NMOS, can improve the dynamic range characteristic. However, the TIA has a disadvantage in that an increase in the size of the NMOS results in an increase in the power consumption, and at the same time, deteriorates the high frequency characteristic.

The present invention has been made in view of the foregoing, and it is an object of the present invention to provide an optical receiver that can maintain linearity of the output voltage signal and also relax the restriction on the high frequency characteristic when a current signal resulting from conversion of an optical signal causes a high current to flow.

### Solution to Problem

To solve the problems described above, and to achieve the object described above, an optical receiver according to an aspect of the present invention includes a light reception element to convert an optical signal that is input into a first current signal and to output the first current signal. Moreover, the optical receiver includes a transimpedance amplifier to convert the first current signal into a voltage signal and to output the voltage signal using a first field effect transistor and a second field effect transistor. Furthermore, the optical receiver includes a current monitor unit to monitor a current magnitude of the first current signal and to output a second current signal having a current magnitude based on the current magnitude of the first current signal. Moreover, the optical receiver includes a back-gate adjustment unit to determine a state of an input-output characteristic of the transimpedance amplifier on a basis of the second current signal and of the voltage signal, and to control, on a basis of a determination result, a back-gate terminal voltage of at least one of the first field effect transistor and the second field effect transistor.

### Advantageous Effects of Invention

An optical receiver according to the present invention has an effect in that it is possible to maintain linearity of the output voltage signal and also relax the restriction on the high frequency characteristic when a current signal resulting from conversion of an optical signal causes a high current to flow.

### BRIEF DESCRIPTION OF DRAWINGS

FIG. 1 is a diagram illustrating an example configuration of an optical communication system according to a first embodiment.

FIG. 2 is a diagram illustrating an example configuration of an optical receiver according to the first embodiment.

FIG. 3 is a diagram illustrating an example of an input-output characteristic of an inverter-based TIA according to the first embodiment.

FIG. 4 is a diagram illustrating an example configuration of a current monitor unit according to the first embodiment.

FIG. 5 is a diagram illustrating an example configuration of a back-gate adjustment unit according to the first embodiment.

FIG. 6 is a flowchart illustrating an operation for controlling an output of the inverter-based TIA in the optical receiver according to the first embodiment.

FIG. 7 is a timing chart illustrating timing of inputting or outputting of each signal, for explaining the operation for controlling the output of the inverter-based TIA in the optical receiver according to the first embodiment.

FIG. 8 is a diagram illustrating an example in which a processing circuit of the optical receiver according to the first embodiment is constituted by dedicated hardware.

FIG. 9 is a diagram illustrating an example in which a processing circuit of the optical receiver according to the first embodiment is constituted by a CPU and a memory.

FIG. 10 is a diagram illustrating an example configuration of an optical receiver according to a second embodiment.

FIG. 11 is a diagram illustrating an example configuration of a back-gate adjustment unit according to the second embodiment.

FIG. 12 is a flowchart illustrating an operation for controlling an output of an inverter-based TIA in the optical receiver according to the second embodiment.

FIG. 13 is a timing chart illustrating timing of inputting or outputting of each signal, for explaining the operation for controlling the output of the inverter-based TIA in the optical receiver according to the second embodiment.

FIG. 14 is a diagram illustrating an example configuration of an optical receiver according to a third embodiment.

FIG. 15 is a flowchart illustrating an operation for controlling an output of an inverter-based TIA in the optical receiver according to the third embodiment.

FIG. 16 is a timing chart illustrating timing of inputting or outputting of each signal, for explaining the operation for controlling the output of the inverter-based TIA in the optical receiver according to the third embodiment.

### DESCRIPTION OF EMBODIMENTS

An optical receiver, an optical termination device, and an optical communication system according to embodiments of the present invention will be described below in detail on the basis of the drawings. It is understood that the described embodiments are not intended to limit the scope of the present invention.

### First Embodiment

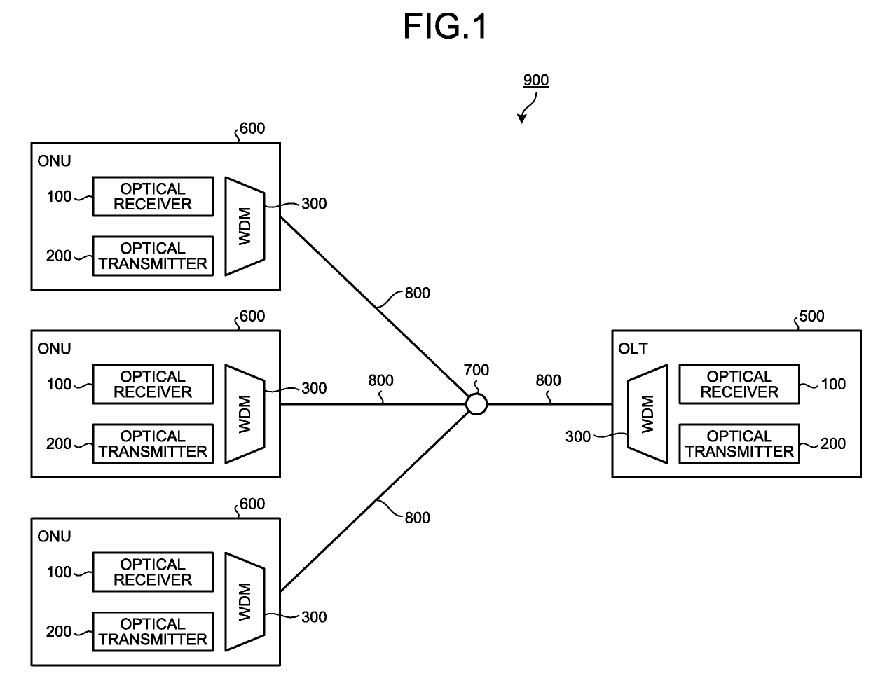

FIG. 1 is a diagram illustrating an example configuration of an optical communication system 900 according to a first embodiment of the present invention. The optical communication system 900 includes an optical line terminal (OLT) 500, optical network units (ONUs) 600, an optical splitter 700, and optical cables 800. The OLT 500, which is an optical termination device in a base station, is connected to multiple ONUs 600, which are each an optical termination device in a subscriber premise, via the optical cables 800 and the optical splitter 700.

The OLT 500 and the ONUs 600 each include an optical receiver 100, an optical transmitter 200, and a wavelength division multiplexing (WDM) 300. The optical receiver 100 converts an optical signal that is input from the optical transmitter 200 of a peer device into an electrical signal, and outputs the electrical signal. The optical transmitter 200 converts an electrical signal that is input from a connection device, such as a terminal not illustrated, into an optical signal, and outputs the optical signal. The WDM 300 multiplexes optical signals on transmitting an optical signal, and on receiving an optical signal, demultiplexes the optical signal. The following description describes in detail the configuration of the optical receiver 100.

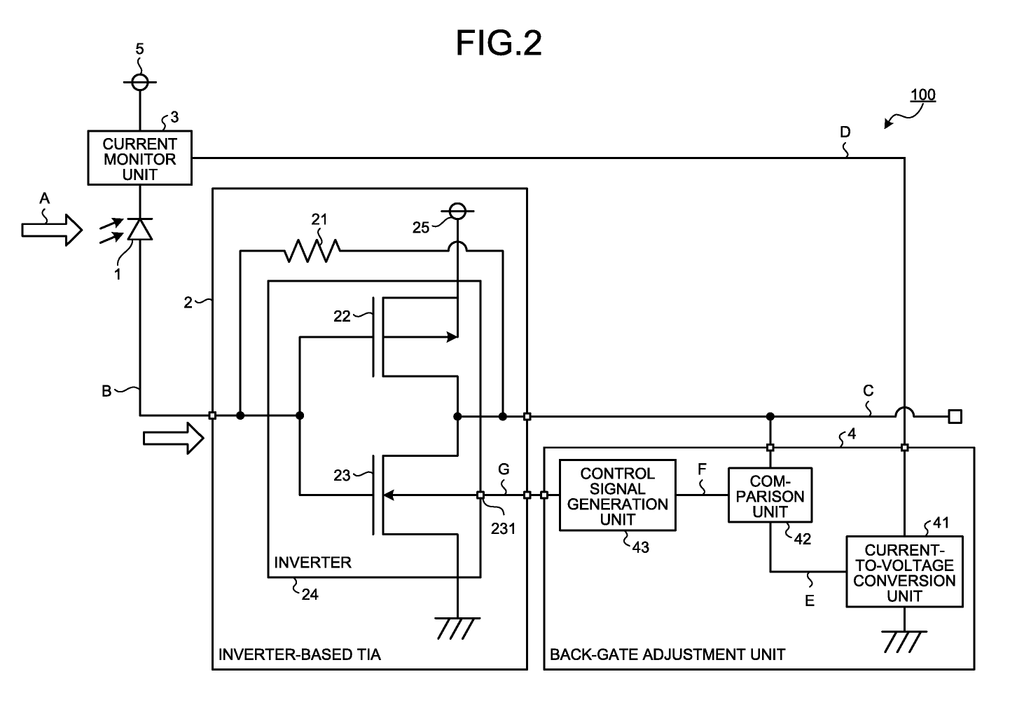

FIG. 2 is a diagram illustrating an example configuration of the optical receiver 100 according to the first embodiment. The optical receiver 100 includes a light reception element 1, an inverter-based TIA 2, a current monitor unit 3, a back-gate adjustment unit 4, and a light reception element-powering power supply 5.

The light reception element 1 performs photoelectric conversion on an optical signal A that is input, to convert the optical signal A into a current signal B, which is a first current signal, and outputs the current signal B.

The inverter-based TIA 2 is a transimpedance amplifier that converts the current signal B into a voltage signal, amplifies the voltage level of the voltage signal, and outputs a voltage signal C, which is a first voltage signal. The inverter-based TIA 2 uses a back-gate terminal 231 of an NMOS 23 therein as a control terminal. The inverter-based TIA 2 is configured to use a complementary MOS (CMOS) circuit useful for a further reduction in power consumption.

The current monitor unit 3 is connected between the light reception element-powering power supply 5 and the cathode terminal of the light reception element 1, and monitors the current magnitude of the current signal B flowing to the light reception element 1. The current monitor unit 3 outputs, on the basis of the current magnitude of the current signal B, a current signal D, which is a second current signal having a current magnitude equal to the current signal B or a current magnitude of a product of a predetermined multiplication factor and the current magnitude of the current signal B. Although the current monitor unit 3 is illustrated as being connected between the light reception element-powering power supply 5 and the cathode terminal of the light reception element 1, the arrangement with respect to the current monitor unit 3 may not necessarily be as illustrated in FIG. 2.

The back-gate adjustment unit 4 determines the state of the input-output characteristic of the inverter-based TIA 2 on the basis of the current signal D output from the current monitor unit 3 and of the voltage signal C output from the inverter-based TIA 2. Specifically, the back-gate adjustment unit 4 converts the current signal D output from the current monitor unit 3 into a voltage signal E, which is a second voltage signal, and compares the voltage of the voltage signal E after the conversion with the voltage of the voltage signal C output from the inverter-based TIA 2 to determine whether the input-output characteristic of the inverter-based TIA 2 is linear or nonlinear. When the ratio between the amount of change in the current signal B input and the amount of change in the voltage signal C is constant, that is, when the relationship between the amount of change in the current signal B input and the amount of change in the voltage signal C can be expressed by a linear equation, this relationship is referred to as being linear. When the ratio between the amount of change in the current signal B input and the amount of change in the voltage signal C is not constant, that is, when the relationship between the amount of change in the current signal B input and the amount of change in the voltage signal C cannot be expressed by a linear equation, this relationship is referred to as being nonlinear.

When the determination indicates that the input-output characteristic of the inverter-based TIA 2 is linear, the back-gate adjustment unit 4 generates a control signal G having a predetermined first fixed voltage value, which is “0” or a fixed value, and outputs the control signal G to the back-gate terminal 231 of the NMOS 23. Otherwise, when the determination indicates that the input-output characteristic of the inverter-based TIA 2 is nonlinear, the back-gate adjustment unit 4 generates the control signal G for controlling the back-gate terminal voltage of the NMOS 23 in the inverter-based TIA 2, specifically, for raising the back-gate terminal voltage, to make the input-output characteristic linear, and outputs the control signal G to the back-gate terminal 231 of the NMOS 23.

The light reception element-powering power supply 5 supplies electrical power to the light reception element 1.

The configuration of the inverter-based TIA 2 will be described below in detail. The inverter-based TIA 2 includes a feedback resistor 21, an inverter 24, and a bias voltage source 25. Note that the configuration of the inverter-based TIA 2 illustrated in FIG. 2 is merely an example and is not limited thereto.

The feedback resistor 21 is connected between both the input terminal of the inverter 24 and the anode terminal of the light reception element 1, and the output terminal of the inverter 24. The feedback resistor 21 converts the current signal B flowing from the light reception element 1 into a voltage signal. As illustrated in FIG. 2, the inverter 24 uses, as the input terminal, the gate terminal of each of a PMOS (P-type MOSFET) 22 and the NMOS 23; and the inverter 24 uses, as the output terminal, the drain terminal of each of the PMOS 22 and the NMOS 23.

The inverter 24 includes the PMOS 22, which is a second field effect transistor having the back-gate terminal and the source terminal connected together, and the NMOS 23, which is a first field effect transistor having the back-gate terminal as a control terminal. In the inverter 24, the PMOS 22 and the NMOS 23 have the gate terminals connected together and the drain terminals connected together; the source terminal of the PMOS 22 is connected to the bias voltage source 25; and the source terminal of the NMOS 23 is connected to ground.

The bias voltage source 25 supplies electrical power to the inverter 24.

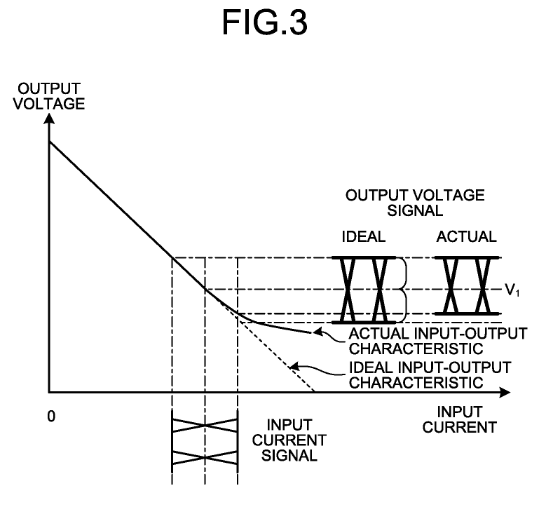

The input-output characteristic of the inverter-based TIA 2 will now be described. FIG. 3 is a diagram illustrating an example of the input-output characteristic of the inverter-based TIA 2 according to the first embodiment. The horizontal axis represents the input current, and the vertical axis represents the output voltage. As described below, FIG. 3 illustrates the characteristic in a case in which no adjustment is made to the back-gate terminal voltage, i.e., the threshold voltage, of the NMOS 23 or the PMOS 22. In the inverter-based TIA 2, a high received-light level or a high extinction ratio of the optical signal input to the light reception element 1 causes a high current of the input current signal to flow from the light reception element 1 through the feedback resistor 21 and the drain terminal of the NMOS 23 to ground. In this process, an increase of the input current signal causes the voltage of the output voltage signal to decrease in accordance with the current magnitude of the flowing current and the resistance value of the feedback resistor 21, but this voltage decrease becomes restricted at a certain voltage level V₁.

In the NMOS 23, the voltage across the gate terminal and the source terminal and the voltage across the drain terminal and the source terminal determine the magnitude of the drain current flowing between the drain terminal and the source terminal. In the NMOS 23, a higher drain current magnitude means a higher voltage across each of these pairs of terminals, but in contrast, the voltage of the output voltage signal, i.e., the drain terminal voltage of the NMOS 23, decreases. Thus, the NMOS 23 operates to reduce the drain current magnitude. Therefore, the gate terminal voltage of the NMOS 23, i.e., the input voltage, rises. This operation causes the NMOS 23 to operate in a nonlinear region, and also in consideration of the balance with the PMOS 22, the increase in the voltage will be restricted. As illustrated in FIG. 3, a restriction of a further decrease in the voltage of the output voltage signal causes the actual input-output characteristic indicated by the solid line to deviate from an ideal input-output characteristic indicated by the dotted line. This produces nonlinear relationship. This nonlinear relationship appears as distortion of the waveform of the output voltage signal.

Referring back to FIG. 2, the configuration of the back-gate adjustment unit 4 will now be described in detail. The back-gate adjustment unit 4 includes a current-to-voltage conversion unit 41, a comparison unit 42, and a control signal generation unit 43.

The current-to-voltage conversion unit 41 linearly converts the current signal D output from the current monitor unit 3 into a voltage signal E using a conversion gain similar to that of the inverter-based TIA 2. That is, the current-to-voltage conversion unit 41 converts the current signal D into the voltage signal E having the same magnitude as the magnitude of the voltage signal C when the input-output characteristic of the inverter-based TIA 2 is linear.

The comparison unit 42 compares the voltage of the voltage signal E output from the current-to-voltage conversion unit 41 with the voltage of the voltage signal C output from the inverter-based TIA 2 to obtain the potential difference, and outputs a voltage signal F, which is a third voltage signal based on the potential difference obtained.

The control signal generation unit 43 is connected to the back-gate terminal 231 of the NMOS 23 in the inverter-based TIA 2. The control signal generation unit 43 determines the state of the input-output characteristic of the inverter-based TIA 2 on the basis of the voltage signal F output from the comparison unit 42, generates the control signal G, which is a first control signal, for controlling the back-gate terminal voltage of the NMOS 23 in the inverter-based TIA 2, and outputs the control signal G to the back-gate terminal 231 of the NMOS 23.

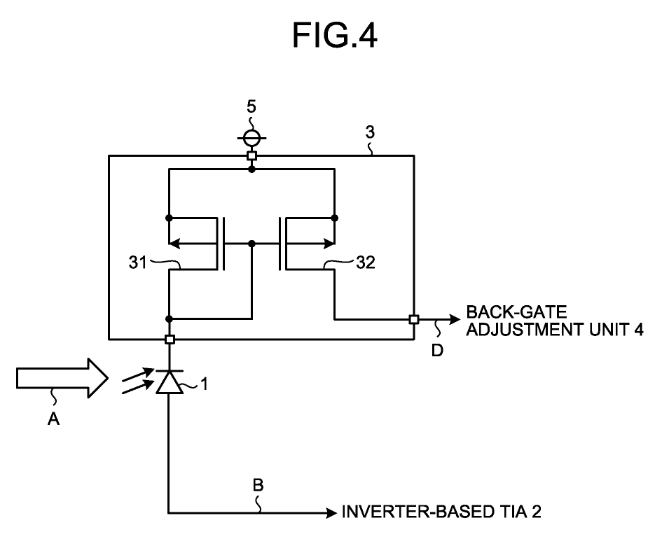

The configuration of the current monitor unit 3 will be described below in detail. FIG. 4 is a diagram illustrating an example configuration of the current monitor unit 3 according to the first embodiment. The current monitor unit 3 includes PMOSs 31 and 32. In the current monitor unit 3, the PMOSs 31 and 32 have the gate terminals connected together and the source terminals connected together; the drain terminal of the PMOS 31 is connected to the cathode terminal of the light reception element 1 and to the gate terminals of the PMOS 31 and of the PMOS 32; and the drain terminal of the PMOS 32 is connected to the input terminal of the back-gate adjustment unit 4, specifically, to the current-to-voltage conversion unit 41. Note that the configuration of the current monitor unit 3 illustrated in FIG. 4 is merely an example and is not limited thereto.

Operations of the light reception element 1 and of the current monitor unit 3 will be described below. When the light reception element 1 receives the optical signal A, the light reception element 1 outputs, from the anode terminal, the current signal B that is in accordance with the received light level. In this process, the light reception element 1 draws, through the cathode terminal thereof, a current signal having the same current value as the current value of the current signal B output from the anode terminal, from the light reception element-powering power supply 5 through the source terminal and the drain terminal of the PMOS 31.

The PMOS 32 of the current monitor unit 3 outputs the current signal D having the same polarity as the polarity of the current signal B flowing to the PMOS 31 and having a current value intensified by a factor that is in accordance with the size ratio between the PMOS 31 and the PMOS 32, from the drain terminal to the input terminal of the back-gate adjustment unit 4. In the current monitor unit 3, use of the same size, i.e., the same characteristic, for the PMOS 31 and the PMOS 32 can provide the current signal B and the current signal D having the same current magnitude. Note that, as described later herein, the current-to-voltage conversion unit 41 of the back-gate adjustment unit 4 performs an amplification process during conversion of the current signal D into the voltage signal E. Thus, it is sufficient that the current signal D output from the current monitor unit 3 have a current magnitude in a range that allows the voltage of the voltage signal E resulting from conversion of the current signal D in the current-to-voltage conversion unit 41 to have the same voltage as the voltage of the voltage signal C, and accordingly, the current magnitude of the current signal D may be lower than the current magnitude of the current signal B.

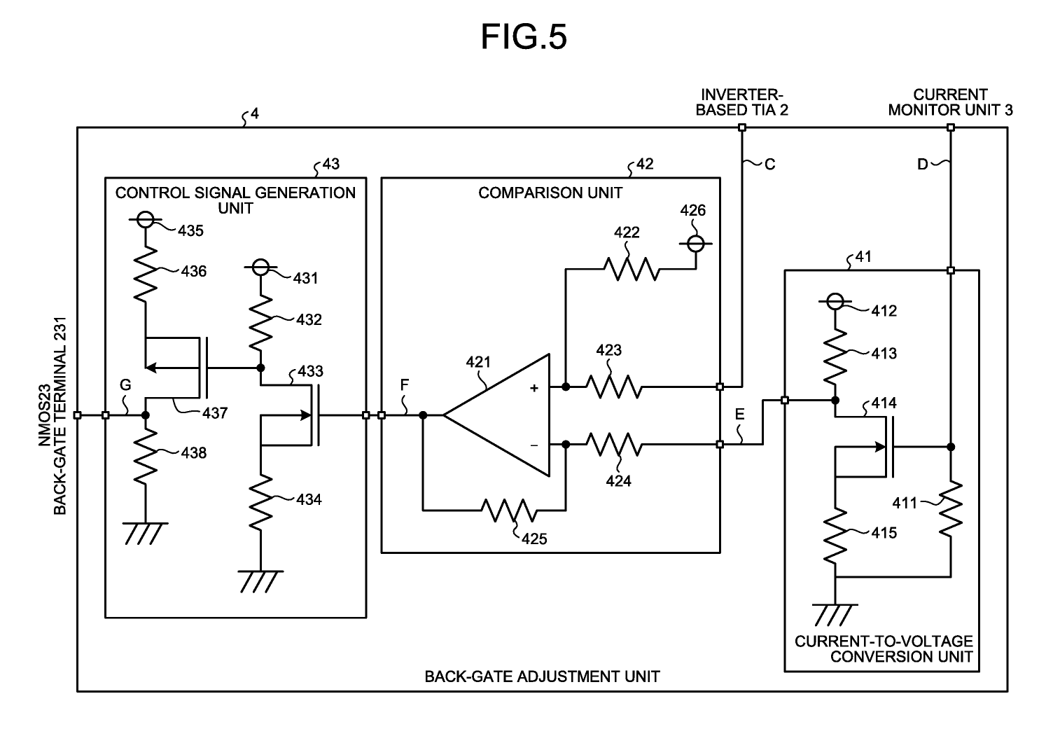

FIG. 5 is a diagram illustrating an example configuration of the back-gate adjustment unit 4 according to the first embodiment. Note that the configuration of each of the current-to-voltage conversion unit 41, the comparison unit 42, and the control signal generation unit 43 illustrated in FIG. 5 is merely an example and is not limited thereto.

The current-to-voltage conversion unit 41 is constituted by a common source amplifier circuit that includes a resistor 411 for converting the current signal D output from the current monitor unit 3 into the voltage signal E, a bias voltage source 412 for matching the polarity and the multiplication factor with the polarity and the multiplication factor of the inverter-based TIA 2, resistors 413 and 415, and an NMOS 414. The current-to-voltage conversion unit 41 outputs, to the comparison unit 42, the voltage signal E resulting from the conversion of the current signal D output from the current monitor unit 3. Note that it is assumed here that the characteristics of the inverter-based TIA 2, i.e., the characteristics of the feedback resistor 21, the PMOS 22, the NMOS 23, and the bias voltage source 25 that constitute the inverter-based TIA 2, are known. Thus, the current-to-voltage conversion unit 41 uses the resistor 411, the bias voltage source 412, the resistors 413 and 415, and the NMOS 414 having characteristics determined such that the voltage of the voltage signal E resulting from the conversion of the current signal D becomes equal to the voltage of the voltage signal C output from the inverter-based TIA 2 when the inverter-based TIA 2 is operating linearly.

The comparison unit 42 includes an operational amplifier 421 having differential inputs and a single-phase output, resistors 422, 423, 424, and 425, and a bias voltage source 426. The comparison unit 42 determines, by the resistors 422 to 425, the amplification factor for outputting the potential difference between the voltage of the voltage signal C output from the inverter-based TIA 2 and the voltage of the voltage signal E output from the current monitor unit 3. In addition, the bias voltage source 426 determines the bias voltage value of the comparison unit 42.

The control signal generation unit 43 includes a common source amplifier circuit using an NMOS 433 and a common source amplifier circuit using a PMOS 437. The control signal generation unit 43 is configured such that these common source amplifier circuits are cascaded together. The common source amplifier circuit using the NMOS 433 is constituted by a bias voltage source 431, resistors 432 and 434, and the NMOS 433. The common source amplifier circuit using the PMOS 437 is constituted by a bias voltage source 435, resistors 436 and 438, and the PMOS 437. The control signal generation unit 43 is configured such that the voltage value of the bias voltage source 435 determines the value of the back-gate terminal voltage of the NMOS 23 during an operation of the inverter-based TIA 2 in a linear region. In addition, the control signal generation unit 43 is configured such that the ratio between the resistance values of the resistors 436 and 438 determines the multiplication factor of the voltage signal F of the comparison unit 42 to generate the control signal G for controlling the back-gate terminal voltage of the NMOS 23 during an operation of the inverter-based TIA 2 in a nonlinear region.

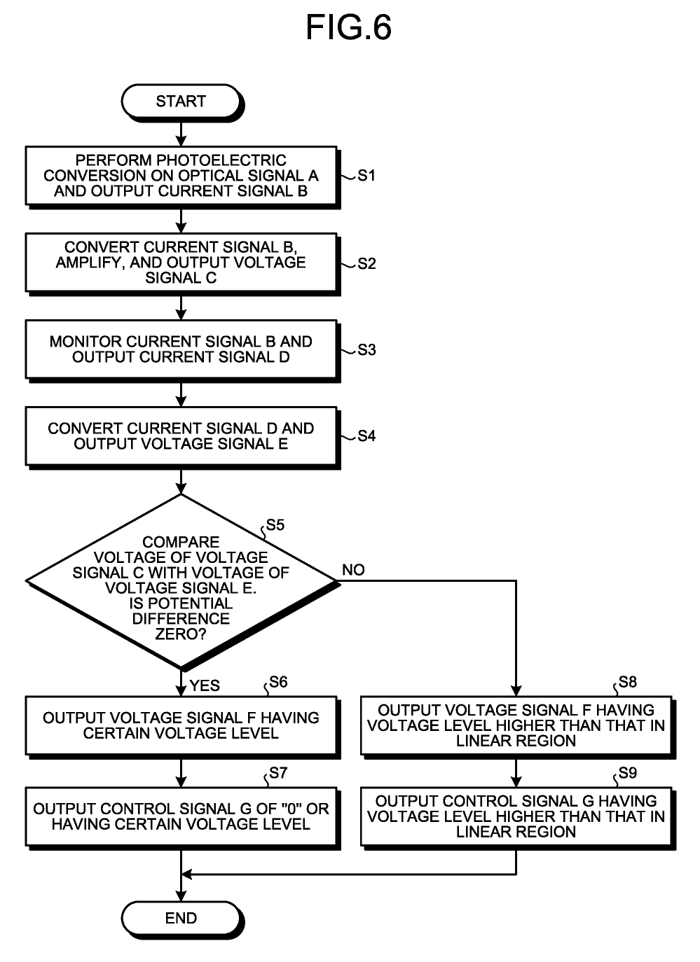

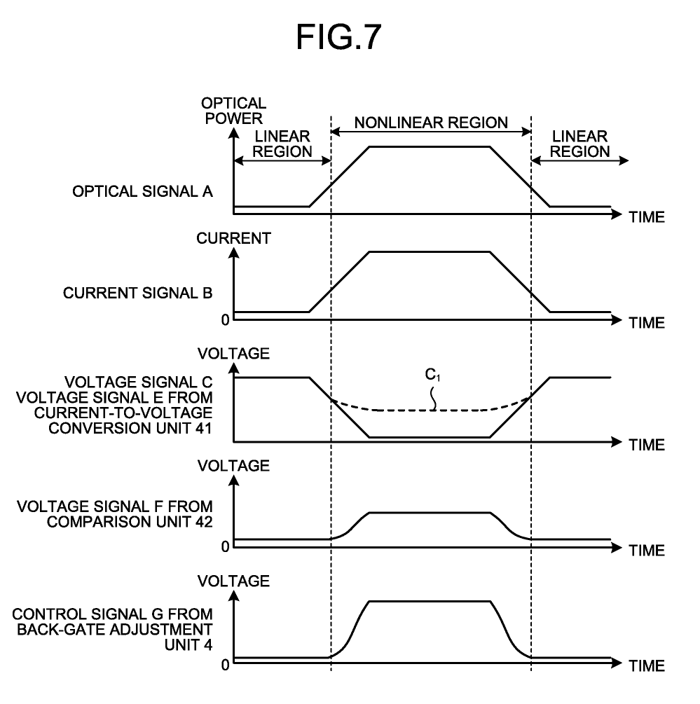

Next, an operation for controlling the output of the inverter-based TIA 2 in the optical receiver 100 will be described. FIG. 6 is a flowchart illustrating an operation for controlling the output of the inverter-based TIA 2 in the optical receiver 100 according to the first embodiment. FIG. 7 is a timing chart illustrating timing of inputting or outputting of each signal, for explaining the operation for controlling the output of the inverter-based TIA 2 in the optical receiver 100 according to the first embodiment. Note that the symbols for the respective signals illustrated in FIG. 7 correspond to the symbols for the respective signals illustrated in the drawings such as FIG. 2.

First, in the optical receiver 100, the light reception element 1 performs photoelectric conversion upon reception of the optical signal A and outputs the current signal B in phase with the optical signal A that has been input, in accordance with the intensity of the optical signal A that has been input, from the anode terminal to the inverter-based TIA 2 (step S1).

In the inverter-based TIA 2, after the current signal B is input, the current signal B flows through the feedback resistor 21 and through the drain terminal and the source terminal of the NMOS 23 to ground. In this process, the inverter-based TIA 2 converts the current signal B into a voltage signal and amplifies the voltage signal by means of the feedback resistor 21, and then outputs the resultant signal as the voltage signal C (step S2).

The current monitor unit 3 monitors the current signal B from the light reception element 1, converts the current signal B on the basis of a multiplication factor determined in the current monitor unit 3, and then outputs the current signal D to the back-gate adjustment unit 4 (step S3).

The current-to-voltage conversion unit 41 of the back-gate adjustment unit 4 converts the current signal D output from the current monitor unit 3 into the voltage signal E having the same polarity and multiplication factor as the polarity and multiplication factor of the voltage signal C output from the inverter-based TIA 2, and then outputs the voltage signal E to the comparison unit 42 (step S4).

In this regard, in the optical receiver 100, when the received light level of the optical signal A is low, that is, the current signal B has a low current value, the inverter-based TIA 2 operates in the linear region illustrated in FIG. 7. In this case, the voltage of the voltage signal C output from the inverter-based TIA 2 and the voltage of the voltage signal E output from the current-to-voltage conversion unit 41 match each other.

The comparison unit 42 compares the voltage of the voltage signal C with the voltage of the voltage signal E, and when the potential difference between the voltage of the voltage signal C and the voltage of the voltage signal E is zero (step S5: Yes), outputs the voltage signal F having a certain voltage level based on the potential difference (step S6).

The control signal generation unit 43 outputs the control signal G of “0” or having a certain voltage level to the back-gate terminal 231 of the NMOS 23 in the inverter-based TIA 2, on the basis of the voltage signal F having a certain voltage level (step S7).

Otherwise, in the optical receiver 100, when the received light level of the optical signal A is high, that is, the current signal B has a high current value, the inverter-based TIA 2 operates in the nonlinear region illustrated in FIG. 7, in other words, operates with the input-output characteristic illustrated in FIG. 3. In this case, as indicated by the dotted line of an uncontrolled voltage signal C₁, the voltage signal C output from the inverter-based TIA 2 is restricted in voltage decrease at a certain voltage level unlike the voltage signal E output from the current-to-voltage conversion unit 41, and thus the voltage of the voltage signal C becomes higher than the voltage of the voltage signal E. This generates a potential difference between the voltage of the voltage signal C and the voltage of the voltage signal E.

The comparison unit 42 compares the voltage of the voltage signal C with the voltage of the voltage signal E. When the potential difference between the voltage of the voltage signal C and the voltage of the voltage signal E is not zero (step S5: No), the comparison unit 42 outputs, on the basis of the potential difference, the voltage signal F having a voltage level higher than the voltage level in the linear region as illustrated in FIG. 7 (step S8).

To control the back-gate terminal voltage of the NMOS 23 in the inverter-based TIA 2 on the basis of the voltage signal F having a voltage level higher than the voltage level in the linear region, the control signal generation unit 43 outputs the control signal G having a voltage level higher than the voltage level in the linear region, i.e., for raising the back-gate terminal voltage of the NMOS 23 as illustrated in FIG. 7 (step S9). As described above, the magnitude of the control signal G is determined by the ratio between the resistance values of the resistors 436 and 438 in the control signal generation unit 43. In the optical receiver 100, the foregoing process is repeated until the inverter-based TIA 2 exhibits a linear input-output characteristic, that is, the potential difference is no more detected by the comparison unit 42. In the back-gate adjustment unit 4, this process causes the voltage of the voltage signal E to transition from the condition of the uncontrolled voltage signal C₁ illustrated in FIG. 7 to the same voltage as the voltage of the voltage signal C indicated by the solid line.

In the inverter-based TIA 2, raising the back-gate terminal voltage under a fixed source terminal voltage of the NMOS 23 can reduce the threshold voltage of the NMOS 23 due to the MOSFET body effect (or substrate bias effect). The lower threshold voltage enables a higher current to flow in the MOSFET without a change in the element size.

The inverter-based TIA 2 would allow a high current to flow from the drain terminal of the NMOS 23 during an input of a high current if no control is provided for the back-gate terminal voltage of the NMOS 23. This would increase the voltage across the drain terminal and the source terminal and would thus impose a restriction of a further decrease in the output voltage thus to cause nonlinearity. In contrast, the inverter-based TIA 2 of the present embodiment raises the back-gate terminal voltage of the NMOS 23 by means of the control signal G from the control signal generation unit 43 to reduce the voltage across the drain terminal and the source terminal even when the same magnitude of current flows to the drain terminal, thereby enabling linearity to be maintained.

Next, the hardware configuration of the optical receiver 100 will be described. In the optical receiver 100, the light reception element 1 is implemented by a photoelectric conversion element. The inverter-based TIA 2 is implemented by circuitry including an inverter circuit, a power supply, and a feedback resistor. The current monitor unit 3 is implemented by a circuit constituted by MOSFETs. The light reception element-powering power supply 5 is implemented by a power supply circuit, a battery, or the like. The back-gate adjustment unit 4, which includes the current-to-voltage conversion unit 41, the comparison unit 42, and the control signal generation unit 43, is implemented by circuitry including a PMOS, NMOSs, resistors, and the like. However, the back-gate adjustment unit 4 may be implemented in software. In this case, the back-gate adjustment unit 4 is implemented by a processing circuit. That is, the optical receiver 100 includes a processing circuit for converting a current signal output from the current monitor unit 3 into a voltage signal, comparing the voltage of the voltage signal from the inverter-based TIA 2 with the voltage of the voltage signal from the current-to-voltage conversion unit 41, and generating a control signal for controlling the back-gate terminal voltage of a MOSFET of the inverter-based TIA 2. The processing circuit may be dedicated hardware or may be a CPU that executes a program stored in a memory and the memory.

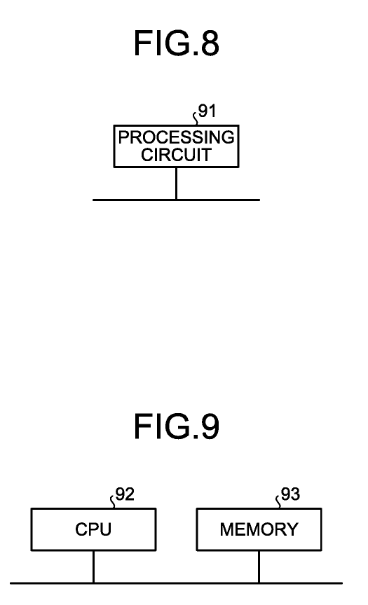

FIG. 8 is a diagram illustrating an example in which the processing circuit of the optical receiver 100 according to the first embodiment is constituted by dedicated hardware. When the processing circuit is dedicated hardware, a processing circuit 91 illustrated in FIG. 8 may be, for example, a single circuit, multiple circuits, a programmed processor, a parallel programmed processor, an application specific integrated circuit (ASIC), a field programmable gate array (FPGA), or a combination thereof. Each of the functions of the components of the back-gate adjustment unit 4 may be implemented by the processing circuit 91 or the functions of the components of the back-gate adjustment unit 4 may together be implemented by the processing circuit 91.

FIG. 9 is a diagram illustrating an example in which the processing circuit of the optical receiver 100 according to the first embodiment is constituted by a CPU and a memory. In a case in which the processing circuit is constituted by a CPU 92 and a memory 93, the functions of the back-gate adjustment unit 4 may be implemented in software, firmware, or a combination of software and firmware. The software or the firmware is described in the form of a program and is stored in the memory 93. In the processing circuit, the functions of the components are implemented by the CPU 92 reading and executing the program stored in the memory 93. That is, the optical receiver 100 includes the memory 93 to store a program which, when executed by the processing circuit, performs a step of converting a current signal output from the current monitor unit 3 into a voltage signal, a step of comparing the voltage of the voltage signal from the inverter-based TIA 2 with the voltage of the voltage signal from the current-to-voltage conversion unit 41, and a step of controlling the back-gate terminal voltage of a MOSFET of the inverter-based TIA 2. In other words, these programs cause a computer to execute the procedure and the method performed by the back-gate adjustment unit 4. Herein, the CPU 92 may be a processing device, a computing device, a microprocessor, a microcomputer, a processor, a digital signal processor (DSP), or the like. The memory 93 may be, for example, a non-volatile or volatile semiconductor memory, such as a random access memory (RAM), a read only memory (ROM), a flash memory, an erasable programmable ROM (EPROM), or an electrically erasable programmable ROM (EEPROM), a magnetic disk, a flexible disk, an optical disk, a compact disc, a Mini Disc, a digital versatile disc (DVD), or the like.

The functions of the back-gate adjustment unit 4 may be implemented partly in dedicated hardware and partly in software or firmware. For example, the functions of the current-to-voltage conversion unit 41 may be implemented by the processing circuit 91 as dedicated hardware, while the functions of the comparison unit 42 and of the control signal generation unit 43 may be implemented by the CPU 92 reading and executing the program stored in the memory 93.

As described above, the processing circuit can provide the foregoing functions by dedicated hardware, software, firmware, or a combination thereof.

As described above, according to the present embodiment, the optical receiver 100 that uses the inverter-based TIA 2 that uses a CMOS circuit useful for a further reduction in power consumption determines the state of the input-output characteristic of the inverter-based TIA 2 on the basis of the monitored signals of the output voltage signal and of the input current signal, and when the state is “nonlinear”, the optical receiver 100 controls the back-gate terminal voltage of the NMOS 23 such that the threshold voltage is reduced. Thus, the optical receiver 100 can relax the restriction on the lower limit of the output voltage, which causes nonlinearity, in the inverter-based TIA 2, by allowing a high drain current to flow. Accordingly, even at a high received-light level, that is, upon an input of a high current caused by a current signal resulting from conversion of such optical signal, a high frequency characteristic, and moreover, a wide input range, can be provided while linearity is maintained to reduce or eliminate distortion of the waveform, without a change in the element size.

### Second Embodiment

The first embodiment has been described in terms of the optical receiver that controls the back-gate terminal voltage of the NMOS 23 in the inverter-based TIA 2. A second embodiment will be described in terms of an optical receiver that controls the back-gate terminal voltage of the PMOS.

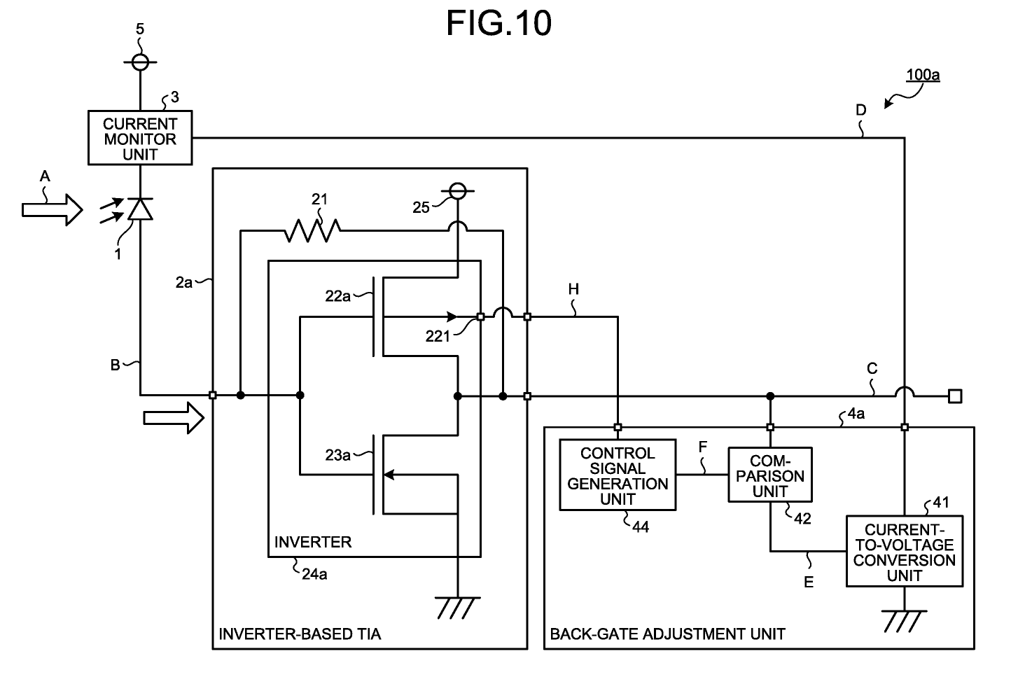

FIG. 10 is a diagram illustrating an example configuration of an optical receiver 100a according to the second embodiment. The optical receiver 100a includes an inverter-based TIA 2a and a back-gate adjustment unit 4a in place of the inverter-based TIA 2 and the back-gate adjustment unit 4 of the optical receiver 100. Note that the configuration of an optical termination device that includes the optical receiver 100a and the configuration of an optical communication system are similar to those illustrated in FIG. 1.

The inverter-based TIA 2a is a transimpedance amplifier that converts the current signal B into a voltage signal, amplifies the voltage level of the voltage signal, and outputs the voltage signal C. The inverter-based TIA 2a uses a back-gate terminal 221 of a PMOS 22a therein as a control terminal. The inverter-based TIA 2a is configured to use a CMOS circuit useful for a further reduction in power consumption.

The configuration of the inverter-based TIA 2a will be described below in detail. The inverter-based TIA 2a includes an inverter 24a in place of the inverter 24 of the inverter-based TIA 2.

The inverter 24a includes the PMOS 22a, which is a second field effect transistor having the back-gate terminal as a control terminal, and an NMOS 23a, which is a first field effect transistor having the back-gate terminal and the source terminal connected together. In the inverter 24a, the PMOS 22a and the NMOS 23a have the gate terminals connected together and the drain terminals connected together; the source terminal of the PMOS 22a is connected to the bias voltage source 25; and the source terminal of the NMOS 23a is connected to ground.

The back-gate adjustment unit 4a determines the state of the input-output characteristic of the inverter-based TIA 2a on the basis of the current signal D output from the current monitor unit 3 and of the voltage signal C output from the inverter-based TIA 2a. Specifically, the back-gate adjustment unit 4a converts the current signal D output from the current monitor unit 3 into the voltage signal E, and compares the voltage of the voltage signal E after the conversion with the voltage of the voltage signal C output from the inverter-based TIA 2a to determine whether the input-output characteristic of the inverter-based TIA 2a is linear or nonlinear.

When the determination indicates that the input-output characteristic of the inverter-based TIA 2a is linear, the back-gate adjustment unit 4a generates a control signal H having a predetermined second fixed voltage value, which is “0” or a fixed value, and outputs the control signal H to the back-gate terminal 221 of the PMOS 22a. The control signal H is a second control signal. Otherwise, when the determination indicates that the input-output characteristic of the inverter-based TIA 2a is nonlinear, the back-gate adjustment unit 4a generates the control signal H for controlling the back-gate terminal voltage of the PMOS 22a in the inverter-based TIA 2a, specifically, for reducing the back-gate terminal voltage, to make the input-output characteristic linear, and outputs the control signal H to the back-gate terminal 221 of the PMOS 22a.

The configuration of the back-gate adjustment unit 4a will be described below in detail. The back-gate adjustment unit 4a includes a control signal generation unit 44 in place of the control signal generation unit 43 of the back-gate adjustment unit 4. The control signal generation unit 44 is connected to the back-gate terminal 221 of the PMOS 22a in the inverter-based TIA 2a. The control signal generation unit 44 determines the state of the input-output characteristic of the inverter-based TIA 2a on the basis of the voltage signal F output from the comparison unit 42, generates the control signal H for controlling the back-gate terminal voltage of the PMOS 22a in the inverter-based TIA 2a, and outputs the control signal H to the back-gate terminal 221 of the PMOS 22a.

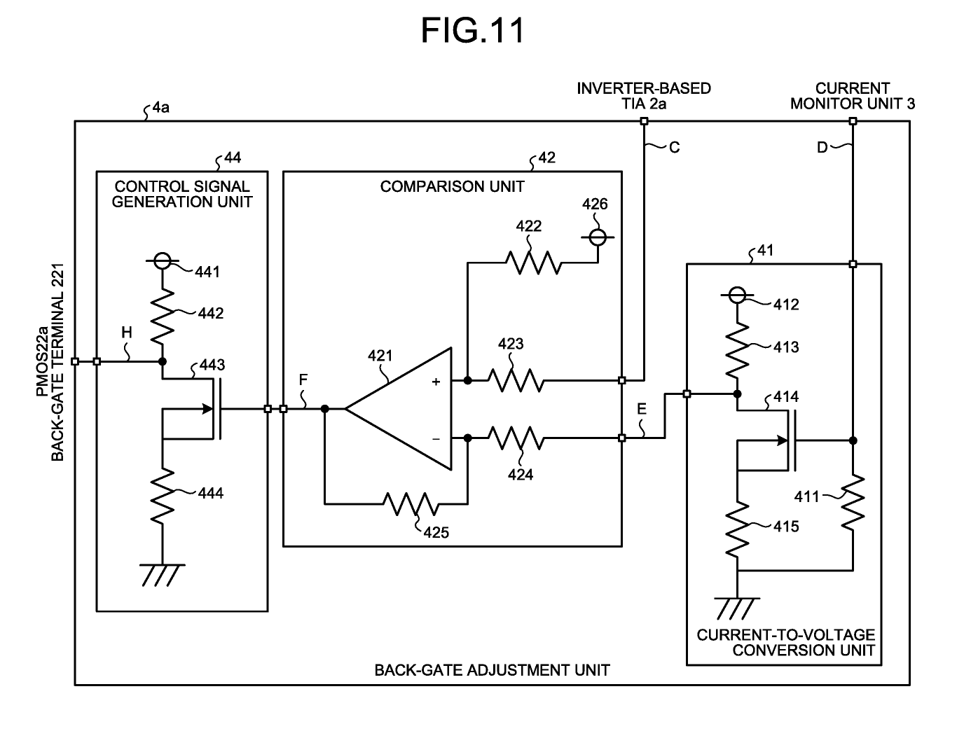

FIG. 11 is a diagram illustrating an example configuration of the back-gate adjustment unit 4a according to the second embodiment. The control signal generation unit 44 is a common source amplifier circuit using an NMOS and includes a bias voltage source 441, resistors 442 and 444, and an NMOS 443. The control signal generation unit 44 is a common source amplifier circuit using the NMOS 443. The common source amplifier circuit using the NMOS 443 is constituted by the bias voltage source 441, the resistors 442 and 444, and the NMOS 443. The control signal generation unit 44 is configured such that the voltage value of the bias voltage source 441 determines the value of the back-gate terminal voltage of the PMOS 22a during an operation of the inverter-based TIA 2a in a linear region. In addition, the control signal generation unit 44 is configured such that the ratio between the resistance values of the resistors 442 and 444 determines the multiplication factor for the voltage signal F of the comparison unit 42 to generate the control signal H for controlling the back-gate terminal voltage of the PMOS 22a during an operation of the inverter-based TIA 2a in a nonlinear region.

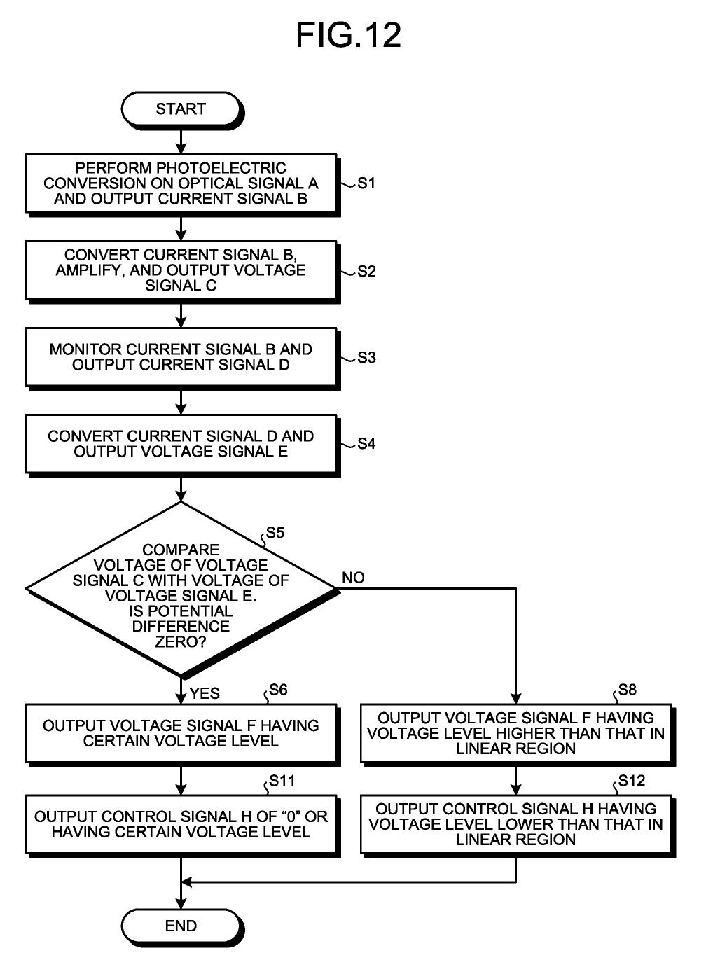

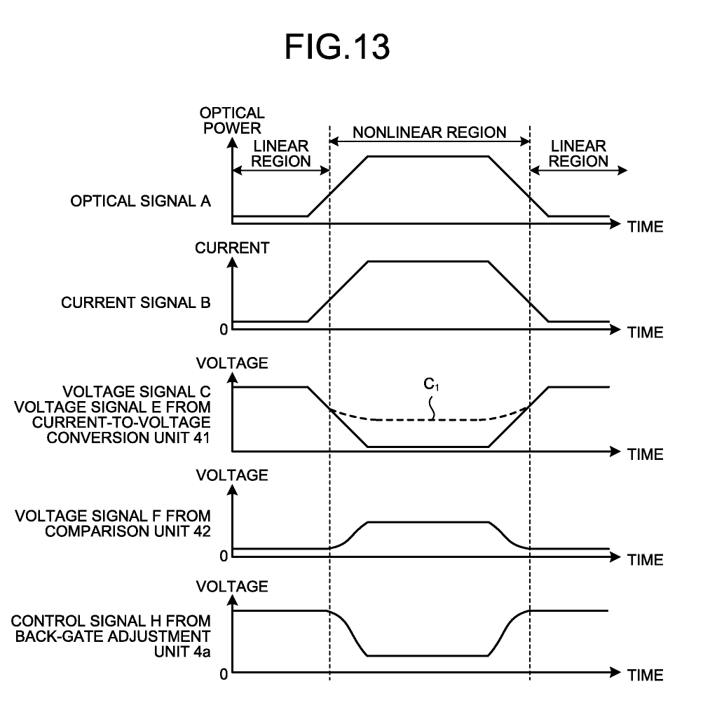

Next, an operation for controlling the output of the inverter-based TIA 2a in the optical receiver 100a will be described. FIG. 12 is a flowchart illustrating an operation for controlling the output of the inverter-based TIA 2a in the optical receiver 100a according to the second embodiment. FIG. 13 is a timing chart illustrating timing of inputting or outputting of each signal, for explaining the operation for controlling the output of the inverter-based TIA 2a in the optical receiver 100a according to the second embodiment. Note that the symbols for the respective signals illustrated in FIG. 13 correspond to the symbols for the respective signals illustrated in the drawings such as FIG. 10.

The optical receiver 100 according to the first embodiment controls the back-gate terminal voltage such that the magnitude of current that can flow to the drain terminal of the NMOS 23 is increased. In contrast, the optical receiver 100a according to the second embodiment controls the back-gate terminal voltage of the PMOS 22a such that the drain current magnitude is reduced to thereby increase the magnitude of input current that flows to the drain terminal of the NMOS 23a.

The process from step S1 to step S6 is similar to the corresponding process of the first embodiment. Note that the components “inverter-based TIA 2”, “NMOS 23”, “back-gate adjustment unit 4”, and “optical receiver 100” in the description of the first embodiment should respectively be read as “inverter-based TIA 2a”, “NMOS 23a”, “back-gate adjustment unit 4a”, and “optical receiver 100a”.

After the process at step S6, the control signal generation unit 44 outputs the control signal H of “0” or having a certain voltage level to the back-gate terminal 221 of the PMOS 22a in the inverter-based TIA 2a, on the basis of the voltage signal F having a certain voltage level (step S11).

Otherwise, in the optical receiver 100a, when the received light level of the optical signal A is high, that is, the input current signal B has a high current value, the inverter-based TIA 2a operates in the nonlinear region illustrated in FIG. 13, in other words, operates with the input-output characteristic illustrated in FIG. 3. In this case, as indicated by the dotted line of the uncontrolled voltage signal C₁, the voltage signal C output from the inverter-based TIA 2a is restricted in voltage decrease at a certain voltage level unlike the voltage signal E output from the current-to-voltage conversion unit 41, and thus the voltage of the voltage signal C becomes higher than the voltage of the voltage signal E. This is due to the current flowing to the drain terminal of the NMOS 23a. This generates a potential difference between the voltage of the voltage signal C and the voltage of the voltage signal E.

In the inverter-based TIA 2a, the current flowing to the drain terminal of the NMOS 23a includes the current signal B through the feedback resistor 21 and the drain current from the PMOS 22a. The PMOS 22a in the inverter-based TIA 2a stays in an ON state even under a high current value of the current signal B because the voltage across the gate terminal and the source terminal thereof is not zero, and thus discharges a current from the drain terminal thereof. Most of this current flows to the drain terminal of the NMOS 23a, thereby causing a restriction on the lower limit of the output voltage generated by the NMOS 23a.

Accordingly, the optical receiver 100a according to the second embodiment detects the potential difference between the voltage of the voltage signal C from the inverter-based TIA 2a and the voltage of the voltage signal E from the current-to-voltage conversion unit 41 in a similar manner to the first embodiment, inverts, in the control signal generation unit 44, the increasing voltage signal F from the comparison unit 42, converts the voltage signal F using the multiplication factor, and then inputs the resultant signal into the back-gate terminal 221 of the PMOS 22a.

Specifically, in a similar manner to the first embodiment, the comparison unit 42 compares the voltage of the voltage signal C with the voltage of the voltage signal E, and when the potential difference between the voltage of the voltage signal C and the voltage of the voltage signal E is not zero (step S5: No), the comparison unit 42 outputs, on the basis of the potential difference, the voltage signal F having a voltage level higher than the voltage level in the linear region as illustrated in FIG. 13 (step S8).

To control the back-gate terminal voltage of the PMOS 22a in the inverter-based TIA 2a on the basis of the voltage signal F having a voltage level higher than the voltage level in the linear region, the control signal generation unit 44 outputs the control signal H having a voltage level lower than the voltage level in the linear region as illustrated in FIG. 13 (step S12). As described above, the magnitude of the control signal H is determined by the ratio between the resistance values of the resistors 442 and 444 in the control signal generation unit 44. In the optical receiver 100a, the foregoing process is repeated until the inverter-based TIA 2a exhibits a linear input-output characteristic, that is, the potential difference is no more detected by the comparison unit 42. In the back-gate adjustment unit 4a, this process causes the voltage of the voltage signal E to transition from the condition of the uncontrolled voltage signal C₁ illustrated in FIG. 13 to the same voltage as the voltage of the voltage signal C indicated by the solid line.

In the inverter-based TIA 2a, an increase in the voltage of the voltage signal F from the comparison unit 42 causes the back-gate terminal voltage of the PMOS 22a to be reduced, thereby causing the threshold voltage to rise due to the MOSFET body effect. This increase in the threshold voltage enables the drain current to be reduced in the MOSFET without a change in the element size. Increasing the threshold voltage of the PMOS 22a can reduce the drain current magnitude of the PMOS 22a and can thus increase the proportion of the input current that can flow to the drain terminal of the NMOS 23a.

That is, in the inverter-based TIA 2a that would be in the nonlinear region if no control is provided for the back-gate terminal voltage of the PMOS 22a upon an input of a high current, it is possible to reduce the magnitude of the current flowing to the drain terminal of the NMOS 23a during an input of an input current. Thus, the inverter-based TIA 2a is allowed to operate without a restriction on the lower limit of the output voltage, thereby enabling linearity to be maintained.

As described above, according to the present embodiment, the optical receiver 100a that uses the inverter-based TIA 2a determines the state of the input-output characteristic of the inverter-based TIA 2a on the basis of the monitored signals of the output voltage signal and of the input current signal, and when the state is “nonlinear”, the optical receiver 100a controls the back-gate terminal voltage of the PMOS 22a such that the threshold voltage is increased to reduce the magnitude of the current flowing to the drain terminal of the NMOS 23a. Thus, the optical receiver 100a can relax the restriction on the lower limit of the output voltage, which causes nonlinearity, in the inverter-based TIA 2a in a similar manner to the first embodiment. Accordingly, even at a high received-light level, that is, upon an input of a high current caused by a current signal resulting from conversion of such optical signal, a high frequency characteristic, and moreover, a wide input range, can be provided while linearity is maintained to reduce or eliminate distortion of the waveform, without a change in the element size.

### Third Embodiment

The optical receiver according to the first embodiment controls the back-gate terminal voltage of the NMOS 23, and the optical receiver according to the second embodiment controls the back-gate terminal voltage of the PMOS 22a. A third embodiment will be described in terms of an optical receiver that controls the back-gate terminal voltage of the NMOS 23 and the back-gate terminal voltage of the PMOS 22a.

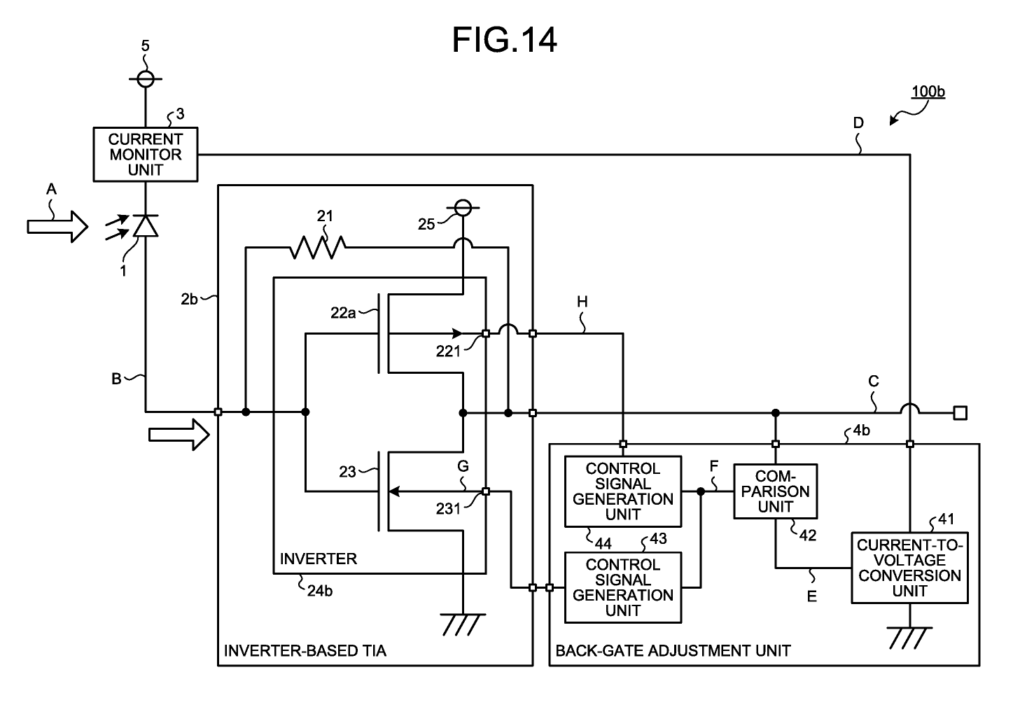

FIG. 14 is a diagram illustrating an example configuration of an optical receiver 100b according to the third embodiment. The optical receiver 100b includes an inverter-based TIA 2b and a back-gate adjustment unit 4b in place of the inverter-based TIA 2 and the back-gate adjustment unit 4 of the optical receiver 100. Note that the configuration of an optical termination device that includes the optical receiver 100b and the configuration of an optical communication system are similar to those illustrated in FIG. 1.

The inverter-based TIA 2b is a transimpedance amplifier that converts the current signal B into a voltage signal, amplifies the voltage level of the voltage signal, and outputs the voltage signal C. The inverter-based TIA 2b uses the back-gate terminal 221 of the PMOS 22a therein and the back-gate terminal 231 of the NMOS 23 therein as c0ontrol terminals. The inverter-based TIA 2b is configured to use a CMOS circuit useful for a further reduction in power consumption.

The configuration of the inverter-based TIA 2b will be described below in detail. The inverter-based TIA 2b includes an inverter 24b in place of the inverter 24 of the inverter-based TIA 2.

The inverter 24b includes the PMOS 22a, which is a second field effect transistor having the back-gate terminal as a control terminal, and the NMOS 23, which is a first field effect transistor having the back-gate terminal as a control terminal. In the inverter 24b, the PMOS 22a and the NMOS 23 have the gate terminals connected together and the drain terminals connected together; the source terminal of the PMOS 22a is connected to the bias voltage source 25; and the source terminal of the NMOS 23 is connected to ground.

The back-gate adjustment unit 4b determines the state of the input-output characteristic of the inverter-based TIA 2b on the basis of the current signal D output from the current monitor unit 3 and of the voltage signal C output from the inverter-based TIA 2b. Specifically, the back-gate adjustment unit 4b converts the current signal D output from the current monitor unit 3 into the voltage signal E, and compares the voltage of the voltage signal E after the conversion with the voltage of the voltage signal C output from the inverter-based TIA 2b to determine whether the input-output characteristic of the inverter-based TIA 2b is linear or nonlinear.

When the determination indicates that the input-output characteristic of the inverter-based TIA 2b is linear, the back-gate adjustment unit 4b generates the control signal G of “0” or having a fixed value, and outputs the control signal G to the back-gate terminal 231 of the NMOS 23. In addition, when the determination indicates that the input-output characteristic of the inverter-based TIA 2b is linear, the back-gate adjustment unit 4b also generates the control signal H of “0” or having a fixed value, and outputs the control signal H to the back-gate terminal 221 of the PMOS 22a.

When the determination indicates that the input-output characteristic of the inverter-based TIA 2b is nonlinear, the back-gate adjustment unit 4b generates the control signal G for controlling the back-gate terminal voltage of the NMOS 23 in the inverter-based TIA 2b, specifically, for increasing the back-gate terminal voltage, to make the input-output characteristic linear, and outputs the control signal G to the back-gate terminal 231 of the NMOS 23. In addition, when the determination indicates that the input-output characteristic of the inverter-based TIA 2b is nonlinear, the back-gate adjustment unit 4b also generates the control signal H for controlling the back-gate terminal voltage of the PMOS 22a in the inverter-based TIA 2b, specifically, for reducing the back-gate terminal voltage, to make the input-output characteristic linear, and outputs the control signal H to the back-gate terminal 221 of the PMOS 22a.

The configuration of the back-gate adjustment unit 4b will be described below in detail. The back-gate adjustment unit 4b includes, in addition to the components of the back-gate adjustment unit 4, the control signal generation unit 44. The control signal generation unit 44 is identical to the control signal generation unit 44 of the second embodiment. In the back-gate adjustment unit 4b, the comparison unit 42 outputs the voltage signal F to the control signal generation units 43 and 44. As used herein, the control signal generation unit 43 is also referred to as a first control signal generation unit and the control signal generation unit 44 is also referred to as a second control signal generation unit.

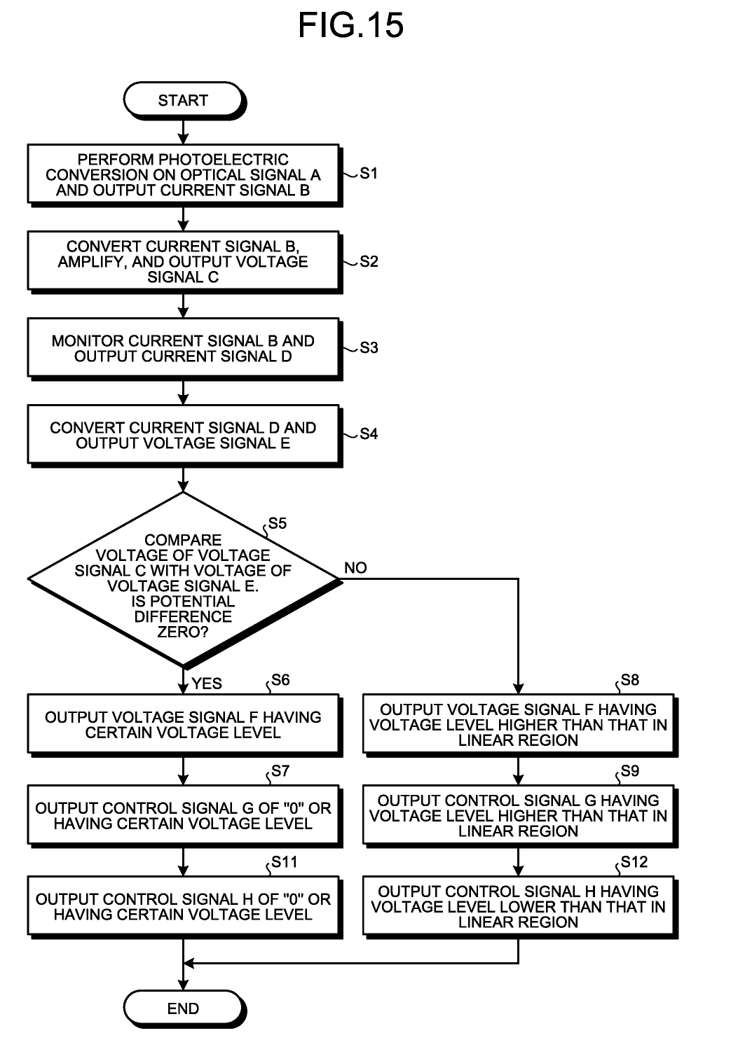

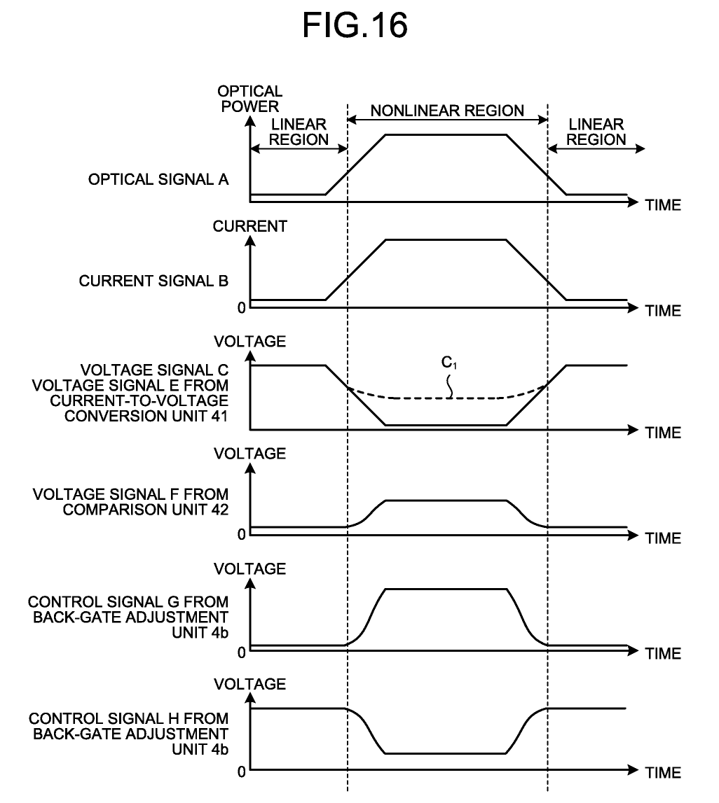

Next, an operation for controlling the output of the inverter-based TIA 2b in the optical receiver 100b will be described. FIG. 15 is a flowchart illustrating an operation for controlling the output of the inverter-based TIA 2b in the optical receiver 100b according to the third embodiment. FIG. 16 is a timing chart illustrating timing of inputting or outputting of each signal, for explaining the operation for controlling the output of the inverter-based TIA 2b in the optical receiver 100b according to the third embodiment. Note that the symbols for the respective signals illustrated in FIG. 16 correspond to the symbols for the respective signals illustrated in FIG. 14.

The process from step S1 to step S6 is similar to the corresponding process of the first embodiment. Note that the components “inverter-based TIA 2”, “back-gate adjustment unit 4”, and “optical receiver 100” in the description of the first embodiment should respectively be read as “inverter-based TIA 2b”, “back-gate adjustment unit 4b”, and “optical receiver 100b”.

After the process at step S6, the control signal generation unit 43 outputs the control signal G of “0” or having a certain voltage level to the back-gate terminal 231 of the NMOS 23 in the inverter-based TIA 2b, on the basis of the voltage signal F having a certain voltage level (step S7).

In addition, the control signal generation unit 44 outputs the control signal H of “0” or having a certain voltage level to the back-gate terminal 221 of the PMOS 22a in the inverter-based TIA 2b, on the basis of the voltage signal F having a certain voltage level (step S11).

Otherwise, in the optical receiver 100b, when the received light level of the optical signal A is high, that is, the input current signal B has a high current value, the inverter-based TIA 2b operates in the nonlinear region illustrated in FIG. 16, in other words, operates with the input-output characteristic illustrated in FIG. 3. In this case, as indicated by the dotted line of the uncontrolled voltage signal C₁, the voltage signal C output from the inverter-based TIA 2b is restricted in voltage decrease at a certain voltage level unlike the voltage signal E output from the current-to-voltage conversion unit 41, and thus the voltage of the voltage signal C becomes higher than the voltage of the voltage signal E. This generates a potential difference between the voltage of the voltage signal C and the voltage of the voltage signal E.

The comparison unit 42 compares the voltage of the voltage signal C with the voltage of the voltage signal E, and when the potential difference between the voltage of the voltage signal C and the voltage of the voltage signal E is not zero (step S5: No), the comparison unit 42 outputs, on the basis of the potential difference, the voltage signal F having a voltage level higher than the voltage level in the linear region as illustrated in FIG. 16 (step S8).

To control the back-gate terminal voltage of the NMOS 23 in the inverter-based TIA 2b on the basis of the voltage signal F having a voltage level higher than the voltage level in the linear region, the control signal generation unit 43 outputs the control signal G having a voltage level higher than the voltage level in the linear region as illustrated in FIG. 16 (step S9).

In addition, to control the back-gate terminal voltage of the PMOS 22a in the inverter-based TIA 2b on the basis of the voltage signal F having a voltage level higher than the voltage level in the linear region, the control signal generation unit 44 outputs the control signal H having a voltage level lower than the voltage level in the linear region as illustrated in FIG. 16 (step S12). In the optical receiver 100b, the foregoing process is repeated until the inverter-based TIA 2b exhibits a linear input-output characteristic, that is, the potential difference is no more detected by the comparison unit 42. In the back-gate adjustment unit 4b, this process causes the voltage signal E to transition from the condition of the uncontrolled voltage signal C₁ illustrated in FIG. 16 to the same voltage as the voltage signal C indicated by the solid line. The optical receiver 100b according to the third embodiment controls both the back-gate terminal voltages of the NMOS 23 and of the PMOS 22a in the inverter-based TIA 2b, and can thus reduce the time required for the inverter-based TIA 2b to exhibit a linear input-output characteristic, that is, the time required for the potential difference to be no more detected by the comparison unit 42, as compared to the cases of the first and the second embodiments.

In the inverter-based TIA 2b, the NMOS 23 operates to reduce the threshold voltage to allow more drain current to flow due to the body effect, and the PMOS 22a operates to increase the threshold voltage of the PMOS 22a to increase the proportion of the current signal B in the total current flowing to the drain terminal of the NMOS 23 and to reduce the drain current due to the body effect. In the inverter-based TIA 2b, this operation increases the magnitude of the current that can flow from the drain terminal of the NMOS 23 and reduces the drain current from the PMOS 22a, thereby reducing the magnitude of the current flowing to the drain terminal of the NMOS 23 for the same input current.

That is, in the inverter-based TIA 2b that would be in the nonlinear region if no control is provided for the back-gate terminal voltage of the NMOS 23 and for the back-gate terminal voltage of the PMOS 22a upon an input of a high current, it is possible to reduce the magnitude of the current flowing to the drain terminal of the NMOS 23 during an input of an input current. Thus, the inverter-based TIA 2b is allowed to operate without a restriction on the lower limit of the output voltage, thereby enabling linearity to be maintained.

As described above, according to the present embodiment, the optical receiver 100b that uses the inverter-based TIA 2b determines the state of the input-output characteristic of the inverter-based TIA 2b on the basis of the monitored signals of the output voltage signal and of the input current signal, and when the state is “nonlinear”, the optical receiver 100b controls the back-gate terminal voltage of the NMOS 23 such that the threshold voltage is reduced to increase the magnitude of the current that can flow to the drain terminal, and at the same time, controls the back-gate terminal voltage of the PMOS 22a such that the threshold voltage is increased to reduce the magnitude of the current flowing to the drain terminal of the NMOS 23. Thus, the optical receiver 100b can relax the restriction on the lower limit of the output voltage, which causes nonlinearity, in the inverter-based TIA 2b in a similar manner to the first and the second embodiments. Accordingly, even at a high received-light level, that is, upon an input of a high current caused by a current signal resulting from conversion of an optical signal, a high frequency characteristic, and moreover, a wide input range, can be provided while linearity is maintained to reduce or eliminate distortion of the waveform, without a change in the element size. In addition, the optical receiver 100b can also reduce the time required for the inverter-based TIA 2b to exhibit a linear input-output characteristic, as compared to the cases of the first and the second embodiments.

The configurations described in the foregoing embodiments are merely examples of various aspects the present invention. These configurations may be combined with other known technologies, and moreover, part of such configurations may be omitted and/or modified without departing from the spirit of the present invention.

### REFERENCE SIGNS LIST

1 light reception element; 2, 2a, 2b inverter-based TIA; 3 current monitor unit; 4, 4a, 4b back-gate adjustment unit; 5 light reception element-powering power supply; 21 feedback resistor; 22, 22a, 31, 32, 437 PMOS; 23, 23a, 414, 433, 443 NMOS; 24, 24a, 24b inverter; 25, 412, 426, 431, 435, 441 bias voltage source; 41 current-to-voltage conversion unit; 42 comparison unit; 43, 44 control signal generation unit; 100, 100a, 100b optical receiver; 200 optical transmitter; 300 WDM; 411, 413, 415, 422, 423, 424, 425, 432, 434, 436, 438, 442, 444 resistor; 421 operational amplifier; 500 OLT; 600 ONU; 700 optical splitter; 800 optical cable; 900 optical communication system.

1. An optical receiver comprising:
a light reception element to convert an optical signal that is input into a first current signal and to output the first current signal;
a transimpedance amplifier to convert the first current signal into a voltage signal and to output the voltage signal using a first field effect transistor and a second field effect transistor;
a current monitor to monitor a current magnitude of the first current signal and to output a second current signal having a current magnitude based on the current magnitude of the first current signal; and
a back-gate adjuster to determine a state of an input-output characteristic of the transimpedance amplifier on a basis of the second current signal and of the voltage signal, and to control, on a basis of a determination result, a back-gate terminal voltage of at least one of the first field effect transistor and the second field effect transistor.

2. The optical receiver according to claim 1, wherein
when the input-output characteristic is linear, the back-gate adjuster outputs a control signal having a fixed voltage value to the first field effect transistor, while when the input-output characteristic is nonlinear, the back-gate adjuster outputs a control signal for raising a back-gate terminal voltage of the first field effect transistor to the first field effect transistor.

3. The optical receiver according to claim 2, wherein
when the voltage signal is referred to as a first voltage signal,
the back-gate adjuster includes
a current-to-voltage converter to convert the second current signal into a second voltage signal,
comparator to compare a voltage of the first voltage signal with a voltage of the second voltage signal to obtain a potential difference and to output a third voltage signal based on the potential difference, and
a control signal generator to determine a state of the input-output characteristic on a basis of the third voltage signal, to generate the control signal, and to output the control signal to a back-gate terminal of the first field effect transistor.

4. The optical receiver according to claim 1, wherein
when the input-output characteristic is linear, the back-gate adjuster outputs a control signal having a fixed voltage value to the second field effect transistor, while when the input-output characteristic is nonlinear, the back-gate adjuster outputs a control signal for reducing a back-gate terminal voltage of the second field effect transistor to the second field effect transistor.

5. The optical receiver according to claim 4, wherein
when the voltage signal is referred to as a first voltage signal,
the back-gate adjuster includes
a current-to-voltage converter to convert the second current signal into a second voltage signal,
a comparator to compare a voltage of the first voltage signal with a voltage of the second voltage signal to obtain a potential difference and to output a third voltage signal based on the potential difference, and
a control signal generator to determine a state of the input-output characteristic on a basis of the third voltage signal, to generate the control signal, and to output the control signal to a back-gate terminal of the second field effect transistor.

6. The optical receiver according to claim 1, wherein
when the input-output characteristic is linear, the back-gate adjuster outputs a first control signal having a first fixed voltage value to the first field effect transistor, and outputs a second control signal having a second fixed voltage value to the second field effect transistor,
while when the input-output characteristic is nonlinear, the back-gate adjuster outputs a first control signal for raising a back-gate terminal voltage of the first field effect transistor to the first field effect transistor, and outputs a second control signal for reducing a back-gate terminal voltage of the second field effect transistor to the second field effect transistor.

7. The optical receiver according to claim 6, wherein
when the voltage signal is referred to as a first voltage signal,
the back-gate adjuster includes
a current-to-voltage converter to convert the second current signal into a second voltage signal,
a comparator to compare a voltage of the first voltage signal with a voltage of the second voltage signal to obtain a potential difference and to output a third voltage signal based on the potential difference,
a first control signal generator to determine a state of the input-output characteristic on a basis of the third voltage signal, to generate the first control signal, and to output the first control signal to a back-gate terminal of the first field effect transistor, and
a second control signal generator to determine a state of the input-output characteristic on the basis of the third voltage signal, to generate the second control signal, and to output the second control signal to a back-gate terminal of the second field effect transistor.

8. An optical termination device comprising:
the optical receiver according to claim 1.

9. An optical communication system comprising:
the optical termination device according to claim 8.
